(19) United States
(12) Patent Application Publication
(10) Pub. No.: US 2003/0190807 A1
(43) Pub. Date: Oct. 9, 2003

(54) Method for manufacturing semiconductor device

(75) Inventors: Eiichi Soda, Kanagawa (JP); Ken Tokashiki, Kanagawa (JP); Atsushi Nishizawa, Kanagawa (JP)

Correspondence Address: SUGHRUE MION, PLLC, 2100 PENNSYLVANIA AVENUE, N.W., WASHINGTON, DC, 20037, US

(73) Assignee: NEC ELECTRONICS CORPORATION

(21) Appl. No.: 10/408,355

(22) Filed: Apr. 8, 2003

(30) Foreign Application Priority Data
Apr. 8, 2002 (JP) 104739/2002

(51) Int. Cl. H01L 21/302; H01L 21/461

(52) U.S. Cl. 438/689; 438/725; 438/710

(57) ABSTRACT

A film containing low dielectric constant MSQ is used for an interlayer insulation film, an opening is provided in the MSQ by use of a resist as a mask, and resist is ashed while the MSQ is exposed. Ashing conditions in this case are set to a low temperature (−20° C. to 60° C.) and lower pressure (5 to 200 mTorr), and RF supply is carried out in the order of bias power and source power. Thus, a CH3 group which determines a low dielectric constant characteristic of the MSQ can be left in the film.

### BACKGROUND OF THE INVENTION

1. Field of the Invention

The present invention relates to a method for manufacturing a semiconductor device, and more particularly to a method for manufacturing a semiconductor device having a low dielectric constant insulation film as an interlayer insulation film.

2. Description of the Prior Art

In recent years, in a damascene popularly used for a high-density wiring method, a low dielectric constant insulation film containing methyl silsesquioxane (MSQ) or the like has been used as an interlayer insulation film. A method for forming a damascene using such a low dielectric constant insulation film will be described by reference to sectional views in FIGS. 1A and 1B.

First, a silicon carbide (via stopper (SiC)) 102, a via interlayer film (MSQ) 103 and an etching stopper (SiC) 104 are sequentially deposited on an underlying Cu wiring 101, and a via hole is formed through a part of the SiC 104 the MSQ 103 and SiC 102. Then, an MSQ 107, an etching stopper (SiC) 108, an antireflection coating (ARC) 109 and a KrF resist 110 are sequentially deposited to form a trench through the KrF resist 110 and the ARC 109. The SiC 108 and the MSQ 107 are etched by use of the trench formed through the KrF resist 110 and the ARC 109 as a mask, and a remaining part of the MSQ 103 is further etched away (FIG. 1A).

Subsequently, the KrF resist 110 and the ARC 109 are removed under normal O₂ ashing conditions, i.e., a high temperature (200° C. to 300° C.), high pressure (0.5 to 2.0 Torr), application of source power (see FIG. 3: power Vₚ applied to a high-frequency coil 12 to generate plasma), and setting of bias power (see FIG. 3: RF high-frequency power for applying an RF high-frequency wave Vₛ to a stage to control incidence energy of ions in the plasma on a wafer 15) to 0 W (FIG. 1B).

However, when the resist is removed under the aforementioned conditions, a residual ratio of a CH₃ group in the MSQ's 103 and 107 becomes 0%, and the MSQ films are completely damaged by O₂ ashing. Regarding a shape of the MSQ after ashing, side walls of the MSQ's 103 and 107 are formed in overhung shapes as shown in FIG. 1B, making it impossible to completely fill openings of the MSQ's with Cu in a subsequent step. Additionally, deterioration of the MSQ films increases dielectric constants of the MSQ's.

Such problems occur because in the ashing using O₂ gas at a high temperature, the CH₃ group in the MSQ easily reacts with oxygen plasma, and is pulled out from MSQ.

### SUMMARY OF THE INVENTION

An object of the present invention is to provide a method for manufacturing a semiconductor device, which uses an ashing method giving no influence to low dielectric constant characteristics of a low dielectric film simultaneously exposed to ashing gas in an ashing step for removing a resist pattern.

A method for manufacturing a semiconductor device according to the present invention, comprises the steps of: forming at least one interlayer insulation film on a substrate; forming a mask pattern made of a photoresist on the at least one interlayer insulation film; etching the at least one interlayer insulation film from its surface by use of the mask pattern as a mask to expose a part of the at least one interlayer insulation film; and removing the mask pattern by ashing using plasma containing oxygen while a part of the at least one interlayer insulation film is exposed. In this semiconductor device manufacturing method, the ashing includes the steps of: applying source power to RF coil located near a wall of a chamber containing the substrate to generate plasma and applying bias power to a stage mounting the substrate to control incidence energy of ions in the plasma on the substrate. A feature of the semiconductor device manufacturing method of the present invention is that in the ashing, the step of applying the bias power is carried out before the step of applying the source power.

In the semiconductor device manufacturing method of the present invention, the bias power is applied 3 to 30 seconds before the source power, and the ashing is carried out under conditions of a temperature of −20° C. to 60° C., gas pressure of 5 to 200 mTorr and the bias power set to incidence energy of ions (peak to peak voltage is approximately equal to ion incidence energy) Vpp=10 to 800 V.

Furthermore, in the semiconductor device manufacturing method of the present invention, the interlayer insulation film contains a CH₃ group, for example, the interlayer insulation film contains methyl silsesquioxane (MSQ) or hydrogen silsesquioxane (HSQ).

### BRIEF DESCRIPTION OF THE DRAWINGS

FIG. 1A is a sectional view of a semiconductor device manufactured by a conventional semiconductor device manufacturing method, showing the manufacturing method in a sequence of steps;

FIG. 1B is a sectional view of the semiconductor device in subsequent manufacturing steps of FIG. 1A.

FIG. 2A is a sectional view of a semiconductor device manufactured by a semiconductor device manufacturing method of a first embodiment of the present invention, showing the manufacturing method in a sequence of steps;

FIG. 2B is a sectional view of the semiconductor device in subsequent manufacturing steps of FIG. 2A;

FIG. 3 is a cross-sectional schematic view of an asher tool;

FIG. 4 is a chemical structure formula of interlayer insulation film of MSQ;

FIGS. 5A and 5B are FT-IR spectra diagram, each of which shows a situation of an intensity change of a CH₃ group spectrum (2900 cm⁻¹) in the MSQ film in a power supply sequence of the asher;

FIG. 6A is a sectional view of a semiconductor device manufactured by a semiconductor manufacturing method of a second embodiment of the present invention, showing the manufacturing method in a sequence of steps;

FIG. 6B is a sectional view of the semiconductor device in subsequent manufacturing steps of FIG. 6A; and

FIG. 6C is a sectional view of the semiconductor device in subsequent manufacturing steps of FIG. 6B.

### DETAILED DESCRIPTION OF THE PREFERRED EMBODIMENTS

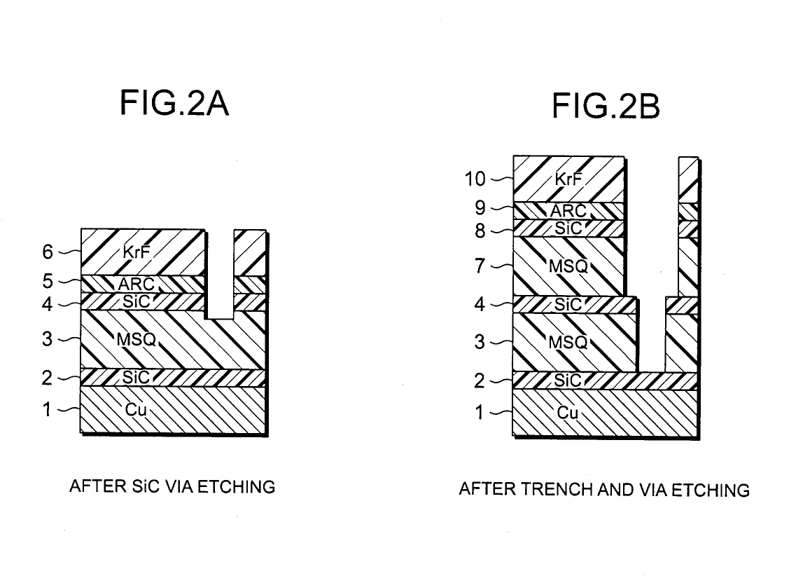

The first embodiment of the present invention will be described with reference to FIGS. 2A, 2B, 3, 4, 5A, and 5B. FIGS. 2A, 2B are sectional views showing partial steps when a dual damascene is formed by a so-called the middle first method.

First, on a lower layer Cu wiring 1, a silicon carbide (etching stopper (SiC)) 2, a via interlayer film (MSQ) 3 and an etching stopper (SiC) 4 are sequentially deposited to 50 nm, 400 nm and 50 nm in thickness, respectively. Then, an antireflection coating (ARC) 5 and a KrF resist 6 are applied, and a via having a diameter of 0.18 μm is exposed and developed in the KrF resist 6.

Then, by use of the KrF resist 6 as a mask, the ARC 5 and the SiC 4 are dry-etched. The etching is carried out by a dual frequency RIE etcher (dual frequency reactive ion etching tool) using CF₄, Ar and O₂ gas plasma. After the etching of the SiC 4, the MSQ 3 is exposed (FIG. 2A).

Subsequently, the KrF resist 6 and the ARC 5 are ashed. However, since the MSQ 3 is exposed, the ashing must be carried out without damaging the MSQ 3, in which case the present invention is applied.

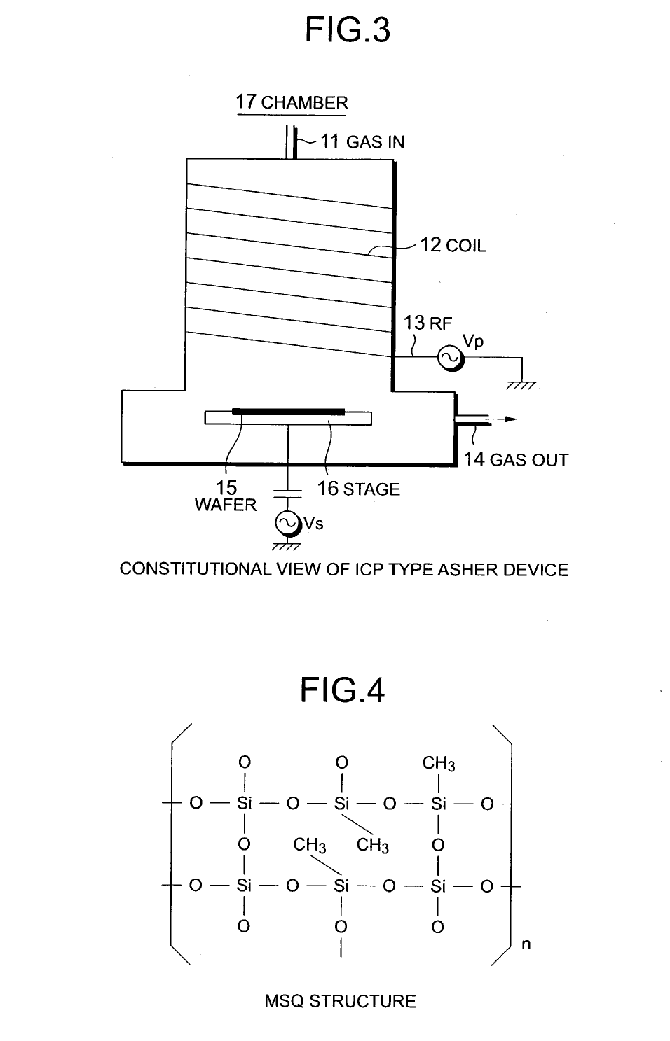

FIG. 3 is a constitutional view of an asher device used in the embodiment. A plasma source is inductive coupled plasma (ICP).

Gas used for ashing is oxygen. The oxygen gas is supplied through a gas introduction line 11 into a vacuum chamber 17. High-frequency power Vₛ is supplied from a RF power source 13 to an RF coil 12, which generates plasma in the vacuum chamber 17. A wafer 15 to be processed is fixed to a stage 16 in the vacuum chamber 17. A temperature of the stage 16 is variable (−20° to 250° C.). The plasma flows down to reach the wafer 15, whereby ashing process can be carried out. A reaction production and a gas after the ashing are pumped out through an exhaust line 14.

The ashing of the embodiment has a largest feature in RF application conditions. First, bias power (RF high-frequency power Vₚ for applying an RF high-frequency wave to the stage 16 and controlling incidence energy of ions in the plasma on the wafer 15) is applied, then source power (power VP applied to the high-frequency coil 12 to generate plasma) is applied in 3 seconds delay. The other ashing conditions of the embodiment are as follows:

gas pressure: 100 mTorr

gas flow rate: O₂: 120 sccm

source power: 1500 W

bias power: 150 W

ashing temperature: 20° C. ashing time: when assuming removal of photoresist and ARC to be removed by ashing theoretically completes upon passage of a time interval, an actual ashing time is set equal to two times the time interval theoretically required for removal of photoresist and ARC (in this case, the latter half of the actual ashing time is referred to as the 100% overashing).

FIG. 4 shows a chemical structure formula of the MSQ.

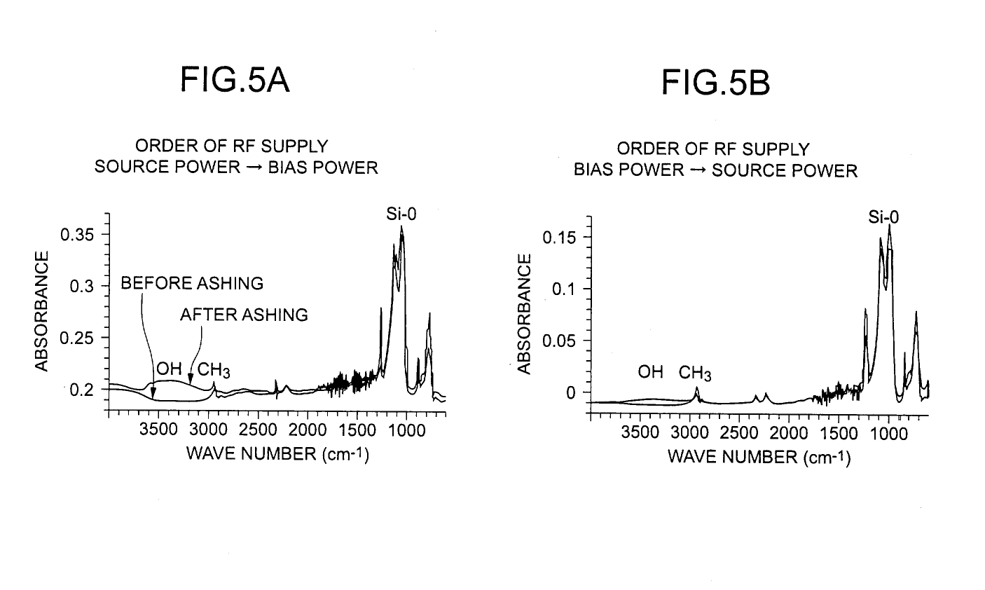

It can be understood that a CH₃ group is coupled to an Si—O chain. Damage of the MSQ caused by the ashing can be evaluated based on a residual ratio of the CH₃ group. The amount of the CH₃ group left in the film is evaluated based on a change in the intensity of a peak (2900 cm⁻¹) on a waveform indicative of the CH₃ group by means of FT-IR after the MSQ having a thickness of 400 nm formed on a whole surface of the wafer is processed under the aforementioned ashing conditions for 2 minutes. In this case, the intensity change of the CH₃ group peak means a change in the CH₃ group spectrum intensity before/after the ashing when the CH₃ group spectrum intensity is normalized by a Si—O spectrum intensity. As a result, as shown in FIGS. 5A and 5B, when the source power is applied first, a residual ratio of the CH₃ group is 67%, giving great damage to the MSQ film. However, when the bias power is applied first, a residual ratio of the CH₃ group is 90%, giving substantially no damage to the MSQ film. Additionally, it can be verified that time from the application of the bias power to the application of the source power is effective for suppressing damage of the MSQ film even in a range of 3 to 30 seconds, and it can be verified-that the resist film can be removed simultaneously.

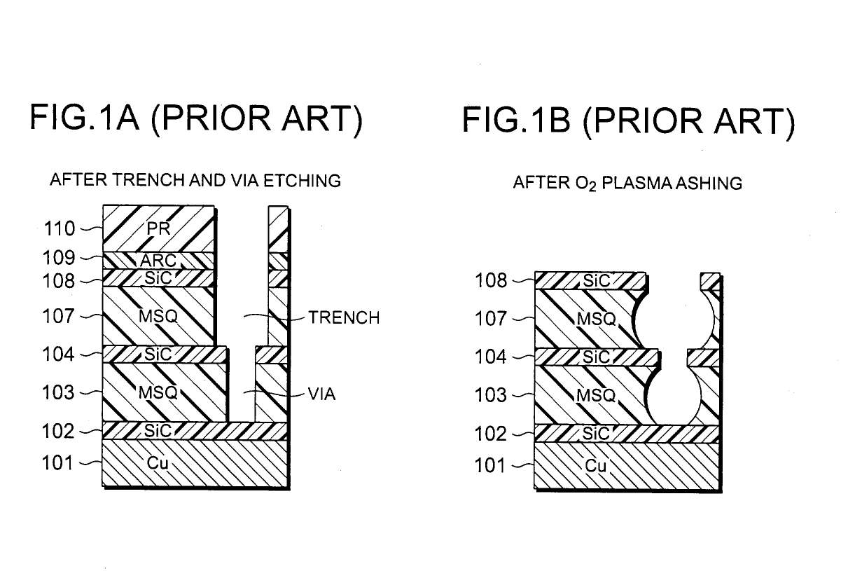

A result of applying the ashing conditions employed in the embodiment to an actual sample for examining the profile of openings shows no overhanging, which is observed when the MSQ 3 is damaged as shown in FIG. 1B.

In the conventional O₂ plasma case, damage of the MSQ can be reduced by applying the ashing conditions of the embodiment. That is, in the O₂ plasma, a processing temperature is set low (100° C. or less) to reduce reactivity between the CH₃ group and the O₂ plasma, gas pressure is set low to increasing etching anisotropy and, further, the bias power is applied before the source power. Thus, a protection film is formed on the surface of the MSQ film to suppress O₂ diffusion in the MSQ. Therefore, the damage suppression of the MSQ film and resist removal can be simultaneously achieved.

Returning to the explanation of the dual damascene forming method in the middle first method of FIGS. 2A and 2B, from the state of FIG. 2A, the KrF resist 6 and the ARC 5 are ashed to be removed. Subsequently, organic peeling solution treatment is carried out to form an MSQ 7 (interlayer insulation film used in formation of trench) of thickness 400 nm and an SiC 8 (hard mask) of thickness 50 nm. By using photolithography of an ARC 9 and a KrF resist a trench image of line and space (L/S)=0.20 μm/0.20 μm is formed. Then, the SiC 8 and the MSQ 7 are dry-etched. CF₄, Ar and O₂ are used for etching gas of the ARC 9 and the SiC 8, while C₄F₈, Ar and N₂ are used for etching gas of the trench MSQ 7. The etching of the trench MSQ 7 is stopped by the SiC 4 stopper, and the via MSQ 3 is successively etched to form a structure similar to that shown in FIG. 2B.

Thereafter, the KrF resist 10 and the ARC 9 are ashed. However, since the MSQ's 3 and 7 are exposed in O₂ plasma, the ashing must be carried out without damaging the MSQ's 3 and 7. Thus, the aforementioned ashing conditions of the embodiment are applied to this process. In the MSQ's 3 and 7, there is no overhanging of the SiC's 4 and 8 after the removal of the resist, verifying effectiveness of the embodiment.

The ashing conditions of the embodiment will be described more in detail. Even in the case of using the O₂ gas plasma while the MSQ as a Cu wiring interlayer film is exposed in O₂ plasma, it is possible to suppress damage by RF supply in the order of bias power and source power under conditions of a low temperature (−20° C. to 60° C.) and low pressure (5 to 200 mTorr). The bias power is set to a condition which satisfies ion incidence energy Vpp=10 to 800 V.

As the ashing tool, any tool can be used as long as they can apply bias power, such as a downflow type plasma asher, an ICP plasma asher (ICP: inductive coupled plasma) or an etching tool (dual frequency RIE: dual frequency reactive ion etching).

As described above, even in the conventional case of the O₂ plasma, the damage suppression of the MSQ film and the resist ashing/removal/strip can be simultaneously achieved by setting a low temperature to reduce reactivity between the CH₃ group and the O₂ plasma, setting low pressure to increase anisotropy for the ion incidence wafer of the O₂ plasma etching, and applying bias power first to form the protection film on the surface of the MSQ film thereby suppressing the O₂ diffusion in the MSQ.

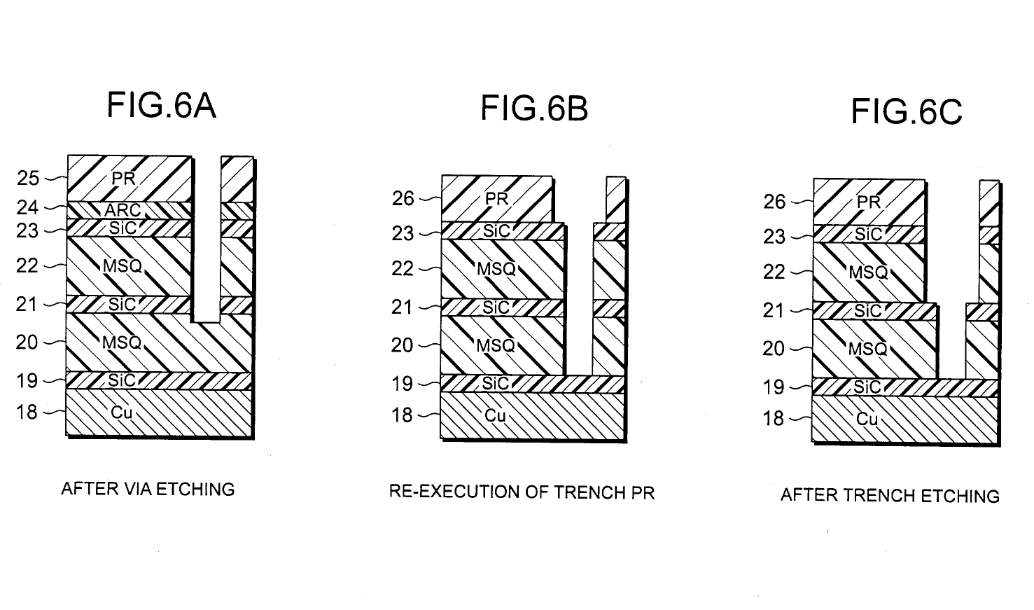

Next, the second embodiment of the present invention will be described with reference to FIGS. 6A and 6B. The first embodiment has been described by way of the ashing process when the dual damascene is formed by the middle first method. The second embodiment will be described by way of example where the present invention is applied to a via first method which is another dual damascene forming method.

On a Cu wiring 18, a via stopper (SiC) 19, an interlayer insulation film used in formation of via (MSQ) 20, a stopper used in formation of trench (SiC) 21, a trench interlayer film (MSQ) 22 and a hard mask (SiC) 23 are formed from the bottom to 50 nm, 400 nm, 50 nm, 400 nm and 50 nm in thickness, respectively. Subsequently, an ARC 24 and a KrF resist 25 are applied, and a via having a diameter of 0.18 μm is patterned by photolithography. Then, by use of the KrF resist 25 as a mask, the ARC 24, the SiC 25, the MSQ 22, the SiC 21 and the MSQ 20 are dry-etched to form a via. For an etching device, a dual frequency RIE etcher is used. Etching gas for the ARC 24 and the SiC's 23 and 22 are CF₄, Ar and O₂, while etching gas for the MSQ's 22, 20 are C₄F₈, Ar and N₂. FIG. 6A shows a shape after the via etching.

Then, the KrF resist 25 and the ARC 24 are removed. Since the MAQ's 22 and 20 are exposed to O₂ plasma, the ashing conditions similar to those of the first embodiment are applied. The ashing can be carried out without damaging the MSQ's 22 and 20.

By using photolithography of a KrF resist 26, and a trench image pattern of L/S=0.20 μm/0.20 μm is formed (FIG. 6B).

Subsequently, by use of the KrF resist 26 as a mask, the SiC 23 and the MSQ 22 are dry-etched to form a trench (FIG. 6C). In this case, if the KrF resist 26 is removed to form a KrF resist pattern again because of an exposure failure, since the MSQ's 22 and 20 are exposed to O₂ plasma during ashing, the ashing conditions similar to those of the first embodiment can be applied. Etching gas for the SiC 23 are CF₄, Ar and O₂, while etching gas for the MSQ 22 are C₄F₈, Ar and N₂. Since the MSQ 22 trench and the MSQ 20 via are exposed to O₂ plasma, by applying ashing conditions similar to those of the first embodiment, ashing can be carried out without damaging the MSQ's 22 and 20.

In the described embodiment, the interlayer insulation film MSQ is used. However, even if HSQ is used instead of MSQ, or SiN or SiON is used instead of the stopper SiC, advantages similar to those of the first embodiment can be obtained.

In the semiconductor device manufacturing method of the present invention, when ashing is carried out for the semiconductor device of the structure using the low dielectric constant MSQ (methyl silsesquioxane) as the interlayer insulation film while the MSQ is exposed, the low temperature (−20° C. to 60° C.) and the low pressure (5 to 200 mTorr) are set as ashing conditions, and RF supply is carried out in the order of bias power and source power. Thus, it is possible to leave a CH₃ group, which decides a low dielectric constant characteristic of the MSQ, in the film.

What is claimed is:

1. A method for manufacturing a semiconductor device, comprising the steps of:
forming at least one interlayer insulation film on a substrate;
forming a mask pattern made of a photoresist on the at least one interlayer insulation film;
etching the at least one interlayer insulation film from a surface thereof by use of the mask pattern as a mask to expose a part of the at least one interlayer insulation film; and
removing the mask pattern by ashing using plasma containing oxygen while a part of the at least one interlayer insulation film is exposed,
wherein the ashing includes the steps of: applying source power to a wall of a chamber containing the substrate to generate plasma in the chamber containing the substrate; and applying bias power to a stage mounting the substrate to control incidence energy of ions in the plasma on the substrate, and the step of applying the bias power is carried out before the step of applying the source power.

2. The method according to claim 1, wherein the step of applying the bias power is carried out 3 to 30 seconds before the step of applying the source power.

3. The method according to claim 1, wherein the ashing is carried out at a temperature of −20° C. to 60° C. with gas pressure of 5 to 200 mTorr, and in the step of applying the bias power, the bias power is set to a condition where incidence energy of ions on the substrate is Vpp=10 to 800 V.

4. The method according to claim 1, wherein the at least one interlayer insulation film includes an interlayer insulation film containing a CH₃ group.

5. The method according to claim 1, wherein the at least one interlayer insulation film includes an interlayer insulation film containing methyl silsesquioxane (MSQ).

6. The method according to claim 1, wherein the at least one interlayer insulation film includes an interlayer insulation film containing hydrogen silsesquioxane (HSQ).
